(19) United States
(12) Patent Application Publication
(10) Pub. No.: US 2017/0048978 A1
(43) Pub. Date: Feb. 16, 2017

(54) CURRENT COLLECTOR FOR AN ENERGY STORAGE ARRANGEMENT, ENERGY STORAGE ARRANGEMENT, IN PARTICULAR FOR A MOTOR VEHICLE, AND MOTOR VEHICLE

(71) Applicant: AUDI AG, Ingolstadt (DE)

(72) Inventors: HEINER FEES, Bietigheim-Bissingen (DE); RALF MAISCH, Abstatt (DE)

(73) Assignee: AUDI AG, Ingolstadt (DE)

(21) Appl. No.: 15/235,949

(22) Filed: Aug. 12, 2016

(30) Foreign Application Priority Data
Aug. 14, 2015 (DE) 10 2015 215 598.6

(51) Int. Cl. H05K 1/18; H01G 4/228; H01M 2/34; H01G 4/38; H01M 10/0525; H01M 2/20

(52) U.S. Cl. CPC H05K 1/18; H01M 10/0525; H01M 2/206; H01M 2/34; H01G 4/38; H01G 4/228; H01M 2220/20; H01M 2200/00

(57) ABSTRACT

A current collector for an energy storage arrangement, includes a busbar having a busbar section and multiple contact sections for electrically conductive connection with a respective end side terminal connection of an energy storage, each of the multiple contact sections having a fastening region and a safety region, wherein the fastening region are configured for fastening the terminal connection of the energy storage on the contact sections, and wherein the safety region is encased by a surface layer and is configured to interrupt the electrically conductive connection when a current flowing through the safety region exceeds a current threshold value.

### CROSS-REFERENCES TO RELATED APPLICATIONS

This application claims the priority of German Patent Application, Serial No. 10 2015 215 598.6, filed Aug. 14, 2015, pursuant to 35 U.S.C. 119(a)-(d), the content of which is incorporated herein by reference in its entirety as if fully set forth herein.

### BACKGROUND OF THE INVENTION

The present invention relates to a current collector for an energy storage arrangement.

The following discussion of related art is provided to assist the reader in understanding the advantages of the invention, and is not to be construed as an admission that this related art is prior art to this invention.

The supply of fully or partially electrically driven motor vehicles requires providing electrical energy from a plurality of energy storages. For this purpose a defined number of energy storages is typically connected by means of a busbar of a current collector in order to then connect the energy storages in parallel for combining the capacities of the energy storages. For this purpose round cells on lithium-ion basis are often used which have a substantially cylindrical outer shape and a terminal connection at an end side.

It is known to electrically conductively connect the busbar with the terminal connections of the energy storages by using a bonding method. The bonding wires used for this purpose are selected to be able to function as a thermal fuse and in the event of a malfunction to interrupt the electrically conductive connection between the busbar and an energy storage. It is also known to guide the bonding wire through a through opening of the busbar and to connect the bonding wire on the side of the busbar that faces away from the energy storage.

However, a disadvantage of bonding processes, in particular the guiding of the bonding wire through the through opening, is that they are very time consuming and due to the small diameters of the bonding wires the electrical connections are error prone. In addition during melting or evaporation of the bonding wire smallest electrically conductive particles are generated which may themselves cause errors such as short circuits or electric arcs through the thus ionized air at the remaining energy storages or electrical components in their vicinity.

It would therefore be desirable and advantageous to provide a current collector, which can be operated more reliably.

### SUMMARY OF THE INVENTION

According to one aspect of the present invention, a current collector for an energy storage arrangement includes a busbar having a busbar section and multiple contact sections for electrically conductive connection with a respective end side terminal connection of an energy storage, each of the multiple contact sections having a fastening region and a safety region, wherein the fastening region is configured for fastening the terminal connection of the energy storage on the contact sections, wherein the safety region is encased by a surface layer and is configured to interrupt the electrically conductive connection when a current flowing through the safety region exceeds a current threshold value.

The invention is based on the idea to dedicate a region of the contact section as safety region, which is shielded against its environment for preventing a distribution of smallest particles that may be generated upon destruction of the safety region in case of a malfunction. For this purpose the current collector according to the invention has the busbar, which can be divided into the contact sections for electrically conductive connection on the energy storage and the safety section for electrically conductive connection between the energy storages. A respective contact section includes the fastening region, in or on which a welding connection with the terminal connection can be generated, and the safety region.

In particular the cross section and/or the material of the safety region predetermines the current threshold value, at the exceedance of which the safety section destructs and thus interrupts the electrically conductive connection between the busbar and the energy storage. In order to prevent the electrically conductive particles that are generated upon destruction of the safety section from becoming distributed in the environment of the safety region it is further provided that the safety region is encased by a surface layer. This surface layer can be arranged on the surface of the safety region by form fit and/or force fit based on adhesion forces.

The current collector according to the invention thus advantageously prevents the distribution of electrically conductive particles upon destruction of the safety region and at the same time a distribution of the particles in the environment of the safety region. As a result the remaining energy storages, the busbar and further components located in the vicinity are protected from contact with the particles and the particles are prevented from causing damage for example due to the generation of short circuits or electric arcs. Particularly advantageously this prevents the occurrence of further errors and enables a reliable operation of the current collector.

According to another advantageous feature of the invention, the surface layer can additionally completely or partially cover the busbar section. The surface layer can thus insulate the busbar against the external environment and provide a touch protection and/or a short circuit protection relative to other electrically conducting objects. Preferably, the busbar section is not covered in those regions that are provided for its external electrical contacting.

According to another advantageous feature of the invention, the surface layer in the region adjoining the safety regions can cover sections of a side of the fastening regions. Advantageously this side is the side of the fastening region which faces away from the terminal connection of the energy storage to be connected, wherein the surface layer surrounds the fastening region in circumferential direction and a central recess for moving a fastening tool into proximity, in particular a welding tool, remains uncovered.

In order to protect the end sides of the energy storage from undesired touching or other contacts with objects it is preferred in the current collector according to the invention when a cover element for at least partially covering the end side of the energy storage to be fastened is molded on the surface layer for each contact section. The cover element thus protrudes from the busbar section and covers the end side, in particular the terminal connection. For this purpose the cover element can advantageously protrude from the side of the busbar facing the terminal connection toward the fastening region. Preferably the cover element has at its free end an additional protrusion, which faces toward the end side of the energy storage.

In order to enable a parallel connection of the energy storages a further busbar can be provided in the energy storage arrangement according to the invention, which further busbar is electrically insulatingly arranged on the first busbar on the side of the terminal connection and has multiple contact elements, wherein at least one respective contact element that can be fastened on a housing is assigned to each of the contact sections. Typically the first busbar is provided for connection with the positive terminals of the energy storages and the further second busbar for connection with the negative terminals of the energy storages. Both busbars are hereby arranged sandwich-like and are mechanically connected with each other. The contact elements are preferably constructed as metal tabs, which protrude from the further busbar and can engage around the housing. Because in many energy storages, in particular in round cells, the housing lies on the negative electrostatic potential of the energy storage the current collector can thus be dimensioned particularly small and in addition during production of the fastenings only has to be worked on at the side which faces away from the energy storages for its fastening.

According to another advantageous feature of the invention, in the current collector having a further busbar the surface layer can extend between the first busbar and the second busbar for insulating the first and second busbar against each other. Thus application of the surface layer can at the same time effect insulation between the busbars and, depending on the selection of the material forming the surface layer, also the mechanical connection between the busbars can be realized.

For further protection of the current collector against touching or contact with other objects the surface layer in the embodiment of the current collector having a further busbar, can also partially cover the further busbar. This applies in particular to the side of the further busbar, which faces away from the first busbar.

According to another advantageous feature of the invention, in the current collector having a further busbar a shield element can be molded on the surface layer for each contact section, which shield element separates the contact section from the at least one contact element. The shield element is preferably formed between the rail section and the contact element and is configured web like. In this case a continuous, in particular ring-segment shaped, opening forms through which the contact elements can be accessed. The shield element shields the terminal connection against the opposite-pole housing so that in particular during the fastening of the energy storages short circuit scan be avoided.

According to another advantageous feature of the invention, the surface layer can be formed by laminating or molding. It is also advantageous when the surface layer is made of a plastic material. Thus injection molding or hot casting methods can be used for generating the surface layer. Beside the formation through lamination however other coating methods can generally also be used.

According to another advantageous feature of the invention, the contact sections can be each formed as a metal tab protruding from the busbar section. This enables a particularly simple fastening of the contact sections on the terminal connections because the terminal connections typically are made of a steel sheet, but the busbar section preferably of aluminum. Due to the difficulties posed by welding steel and aluminum together a metal tab made of steel, nickel or an alloy thereof is preferably used. The metal tab is also preferably arranged on the side of the busbar section that faces the energy storage to be fastened to the further busbar in order to avoid a laborious passage through a through opening.

The use of a welding process for fastening the contact sections on the terminal connections is also facilitated when in the current collector according to the invention the contact sections are deformable for pressing against the energy storage to be fastened on them. During fastening it can thus be ensured that the fastening regions rest flat against the terminal connections and no gaps are created that may interfere with welding. Advantageously the surface layer that encases the safety regions hereby also improves the mechanical stability of the deformable contact sections.

According to another advantageous feature of the invention, the contact sections can be offset when viewed in cross section. The contact sections thus can have a protrusion extending from the busbar section of the first busbar to the terminal connection, wherein via the width of the offset a distance can be adjusted between a plane in which the terminal connections are arranged and a plane in which the first busbar is located.

According to another advantageous feature of the invention, the first busbar can have a through opening for each contact section for moving a fastening tool into proximity of the end side of the energy storage to be fastened. This through opening facilities guiding of the fastening tool, in particular welding tool, to the fastening regions of the contact sections and/or the contact elements of the further busbar.

According to another aspect of the invention, an energy storage arrangement, in particular for a motor vehicle, includes multiple energy storages, each having a terminal connection and a housing, wherein the terminal connection is arranged at a respective end side of the energy storages and lying on an electrostatic potential of a first terminal, wherein the housing lies on an electrostatic potential of a second terminal; a first busbar arranged at the end side of the energy storages, wherein the first busbar has a busbar section and multiple contact sections, each of the multiple contact sections having a fastening region and a safety region, wherein the fastening region is electrically conductively fastened on the terminal connection of respective ones of the energy storages to form an electrically conductive connection between the first busbar and the terminal connection, wherein the safety region is encased by a surface layer and configured to interrupt the electrically conductive connection when a current flowing through the safety region exceeds a current threshold value; and a second busbar arranged on the end side of the energy storages and electrically insulatingly arranged on the first busbar, wherein the second busbar has multiple contact elements, with at least one of the contact elements being electrically conductively fastened to a respective one of the energy storages.

Typically the first terminal is the positive terminal and the second terminal the negative terminal of a respective energy storage. Preferably the energy storage arrangement according to the invention is used in motor vehicles but may also be used in other land vehicles that have users that have to be supplied, such as rail bound vehicles, but may also be installed in other vessels such as air vessels and space or water vessels. In addition also stationary applications are conceivable such as use as a buffer storage for the supply of a low-voltage network of a building.

According to another advantageous feature of the invention, the energy storages can be fastened on the fastening regions and the contact elements by means of a welding connection. Compared to conventional fastenings by means of bonding, significantly more robust mechanical connections of the first busbar on the terminal connections and/or the contact elements on the housings can be generated. This has the particular advantage that a mechanical weak point in the form of bonding wires is removed.

According to another advantageous feature of the invention, the housings can be configured cup-shaped and have a cylindrical outer shape. Such a construction corresponds substantially to the energy storages in then form of round cells such as of the type 18650. The energy storage arrangement can therefore advantageously be constructed on a solid technological basis. Hereby the energy storages have a cover element that closes the cup-shaped housing and includes the terminal connection and closes the hosing insulatingly against the terminal connections. Thus the further busbar can be fastened particularly easily on a border region of the housing. The fact that the border region lies in a plane that is only slightly spaced apart from the terminal connection, additionally enables a particularly space-saving arrangement of the first busbar and the further busbar relative to each other.

According to another aspect of the a motor vehicle includes at least one energy storage arrangement, wherein the at least one energy storage arrangement includes multiple energy storages, each having a terminal connection and a housing, wherein the terminal connection is arranged at a respective end side of the energy storages and lying on an electrostatic potential of a first terminal, wherein the housing lies on an electrostatic potential of a second terminal; a first busbar arranged at the end side of the energy storages, wherein the first busbar has a busbar section and multiple contact sections, each of the multiple contact sections having a fastening region and a safety region, wherein the fastening region is electrically conductively fastened on the terminal connection of respective ones of the energy storages to form an electrically conductive connection between the first busbar and the terminal connection, wherein the safety region is encased by a surface layer and configured to interrupt the electrically conductive connection when a current flowing through the safety region exceeds a current threshold value; and a second busbar arranged on the end side of the energy storages and electrically insulatingly arranged on the first busbar, wherein the second busbar has multiple contact elements, with at least one of the contact elements being electrically conductively fastened to a respective one of the energy storages.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 shows a top view onto a first busbar and a second busbar for explaining the construction of a current collector according to the invention;

FIG. 2 shows a top view onto an energy storage arrangement according to the invention including the current collector according to the invention; and

FIG. 3 shows a sectional view along the sectional plane III-III of the energy storage arrangement in the end side region of ta n energy storage.

### DETAILED DESCRIPTION OF PREFERRED EMBODIMENTS

Throughout all the Figures, same or corresponding elements may generally be indicated by same reference numerals. These depicted embodiments are to be understood as illustrative of the invention and not as limiting in any way. It should also be understood that the figures are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

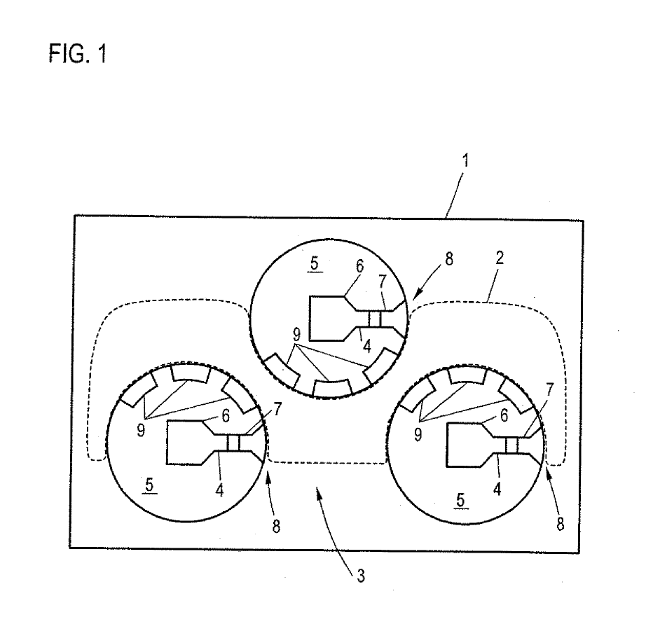

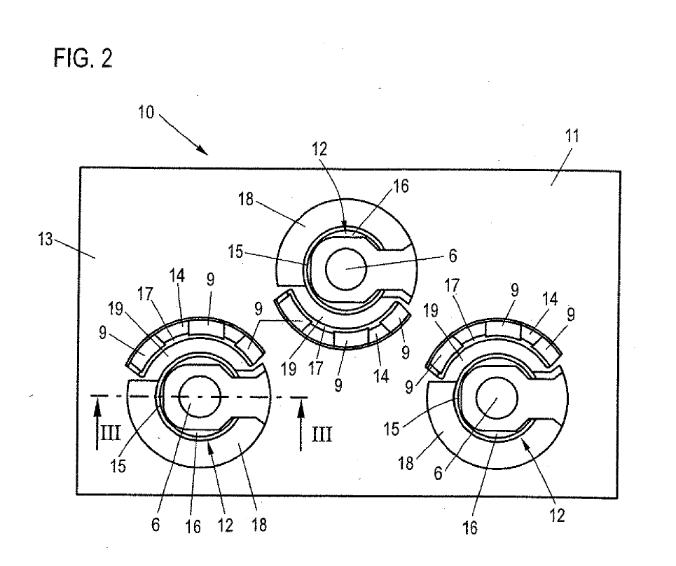

FIG. 1 shows an arrangement of a first busbar 1 and a further busbar 2 covered by the first busbar for explaining the construction of the current collector shown in FIG. 2.

The first busbar 1 has a busbar section 3 and three contact sections 4, which are each constructed as metal tabs and protrude from the busbar section 3 into a though opening 5 of the first busbar 1. Each contact section 4 includes a fastening region 6 and a safety region 7, which due to its cross section and the material of which it is made is configured to destruct when a current flowing thought the safety region exceeds a current threshold value. As a result an electrically conductive connection between the busbar section 3 and the fastening section 6 is interrupted.

The further busbar section 2 is located in top view below the first busbar 1 and has three recesses 8 whose borders partially extend parallel to the border of the though openings 5. In each of the recesses 8 three contact elements protrude from the further busbar 2 and are also configured as metal tabs.

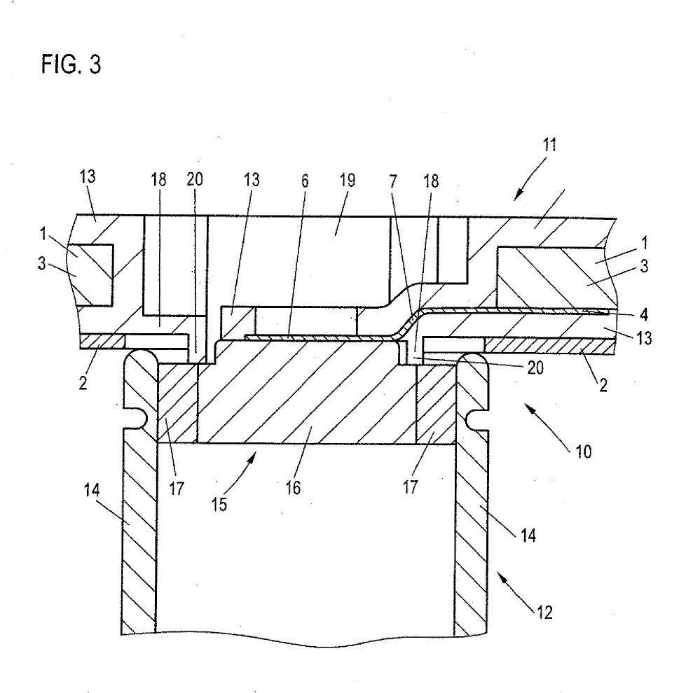

FIGS. 2 and 3 show an energy storage arrangement 10 including a current collector 11 and three energy storages 12 fastened on the current collector. The current collector 11 includes the first busbar 1 and the further busbar 2 of FIG. 1, wherein in addition a surface layer 13 made of an electrically insulating material which was applied onto the first busbar 1 by molding in an injection molding or hot casting process or by a coating method such as for example laminating.

FIG. 2 shows a top view of the energy storage arrangement 10. The energy storages 12 are for example round cells on lithium-ion basis of the type 18650 with a cylindrical outer shape. The energy storages 12 each include a cup-shaped housing 14, which is closed by a cover element 15, which is arranged at the end side. the cover element 15 has a terminal connection 16 and an insulating ring 17, which electrically insulates the terminal connection 16 against the housing 14. The terminal connection 16 hereby lies on the electrostatic potential of the positive terminal of the energy storage 12 and the housing 14 on the negative electrostatic potential of the energy storage 12.

Each energy storage 12 is respectively connected with the fastening region 6 of a contact section 4, wherein in FIG. 2 only a part of each fastening region 6 is visible because the remaining parts of the contact sections 4 are covered by the surface layer 13. In addition the housing 14 of each energy storage 12 is electrically conductively fastened on the three contact elements 9, which engage around a border region of the housing 14. The fastening of the contact elements 9 on the housing 14 and the fastening region 6 of the contact sections 4 on the terminal connections 16 of the energy storages 12 is generated by welding, in particular by a laser welding process.

The surface layer 13 covers the entire side of the first busbar 1 that faces away from the energy storages 12 except for a section of the fastening regions 6 of the contact sections 4 that is provided for a welding point. Hereby in particular the safety regions 7 of the contact sections 4 are encased by the surface layer 13. This prevents that upon destruction of the metal tabs in the safety region 7 the particles generated thereby can escape to the outside. The particles may otherwise themselves lead to malfunctions such as short circuits or electric arcs on the energy storages 12, the current collector device 11 or other electrical components located in the vicinity of the energy storage arrangement 10.

As described above the surface layer 13 covers sections of the fastening regions 6 in order to protect the terminal connections 12 from contact with other objects which may themselves cause malfunctions such a short circuit or an electric arc. In addition a cover element 18 is molded to the surface layer 13 in the region of each through opening 5, which cover element covers the end side cover elements 15 of the energy storages 12 and also serves for touch protection.

In addition a shield element 19 is provided for each energy storage 12, which is molded to the surface layer 13 in the manner of a web and which separates the contact elements 9 on the housing 14 from the contact section 4 and the terminal connection 16. This ensures that when moving a fastening tool into proximity of the contact elements 9 or the fastening sections 6 no undesired short circuits or electric arcs are generated.

FIG. 3 shows a sectional view of the energy storage arrangement 10 along the sectional plane III-III. Hereby all explanations regarding the exemplary shown one energy storage 12 also apply to the other parts of the energy storage arrangement 10.

As can be seen the surface layer 13 also extends on the side of the first busbar 1 which faces the further busbar 2 and thus ensures their mutual insulation and at the same time mechanical connection. The current collector 11 thus forms a sandwich like assembled component for fastening on the energy storages 12.

The cover element 18 is configured lowered relative to the remaining surface layer 13 on the side of the busbar section 3 of the first busbar which side faces away from the of the busbar section 3 of the first busbar 1 in order to leave a greatest possible free space for moving the welding tool into proximity. The cover element 18 also has an additional protrusion 20, which rests with the insulating ring 17 on the cover element 15 in a contact region of the terminal connection 16. In contrast to the cover element 18 the shield element 19 is not configured lowered and ends flush with the surface layer 13 on the side of the busbar section 3 which faces away from the further busbar 2.

On the side of the terminal connection or the side of the busbar section 3 that faces the further busbar 2 the contact section 4 is arranged on the busbar section 3 of the first current collector device 1, which enables connection of the contact section 4 to the busbar section 3 with significantly less effort than in conventional devices in which a bonding wire first has to be passed through a through opening. In the region of its safety section 7 the contact section 4 also has an offset in the direction of the terminal connection 16. The offset enables a particularly easy pressing of the deformable contact section 4 during the generation of the welding connection. As further illustrated the safety region 7 is encased on both sides by the surface layer 13 and thus no electrically conductive particles can escape to the outside upon exceedance of the current threshold value. Thus a significantly more reliable operation of the energy storage arrangement 10 and the current collector device 11 is made possible.

In further exemplary embodiments it is also conceivable that the surface layer 13 additionally extends to a side of the further busbar 2 which faces away from the first busbar 1 in order to achieve a more comprehensive insulation of the current collection device 10 toward the outside.

The energy storage arrangement 10 is preferably used for providing electrical energy in a motor vehicle, in particular of the supply of a partially or fully electrically driven drive aggregate. Such an application is also conceivable in other land vehicles such as rail bound vehicles, but also in air vessels space vessels or water vessels. The energy storage arrangement 10 can also be used in stationary scenarios for example as buffer storage in a building whose low voltage network can be decentrally supplied.

While the invention has been illustrated and described in connection with currently preferred embodiments shown and described in detail, it is not intended to be limited to the details shown since various modifications and structural changes may be made without departing in any way from the spirit of the present invention. The embodiments were chosen and described in order to best explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A current collector for an energy storage arrangement, said current collector comprising:
a busbar having a busbar section and multiple contact sections for electrically conductive connection with a respective end side terminal connection of an energy storage, each said multiple contact sections having a fastening region and a safety region, said fastening region being configured for fastening the terminal connection of the energy storage on the contact sections, said safety region being encased by a surface layer and configured to interrupt the electrically conductive connection when a current flowing through the safety region exceeds a current threshold value.

2. The current collector of claim 1, wherein the surface layer partially or completely covers the busbar section.

3. The current collector of claim 1, wherein on a side adjoining the safety regions the surface layer covers sections of a side of the fastening regions.

4. The current collector of claim 1, further comprising a cover element formed on the surface layer for each contact section, said cover element at least partially covering the end side of the energy storage.

5. The current collector of claim 1, further comprising a further busbar provided on a side of the terminal connection and being electrically insulatingly arranged on the busbar, said further busbar having multiple contact elements, with at least one of the contact elements being fastenable on a housing of the energy storage and assigned to the contact sections.

6. The current collector of claim 5, wherein the surface layer extends between the busbar and the further busbar for insulating the and the further busbars against each other.

7. The current collector of claim 5, wherein the surface layer additionally covers sections of the second busbar.

8. The current collector of claim 5, further comprising a shielding element for each contact section, said shield element being formed on the surface layer and separating the contact section from the at least one contact element.

9. The current collector of claim 1 wherein the surface layer is formed by laminating or injection molding.

10. The current collector of claim 1, wherein the surface layer is made of a plastic material.

11. The current collector of claim 1, wherein the contact sections are each configured as a metal tab which protrudes from the busbar section.

12. The current collector of claim 1, wherein the contact sections are deformable for pressing the contact sections on a respective one of the energy storage to be fastened on a respective one of the contact sections.

13. The current collector of claim 1, wherein the contact sections are offset in a direction of the terminal connections when viewed in cross section.

14. The current collector of claim 1, wherein the busbar has a through opening for each of the contact sections for passage therethrough of a fastening tool into proximity of the end side of the energy storage.

15. An energy storage arrangement, comprising:
multiple energy storages, each having a terminal connection and a housing, said terminal connection being arranged at a respective end side of the energy storages and lying on an electrostatic potential of a first terminal, said housing lying on an electrostatic potential of a second terminal;
a first busbar arranged at the end side of the energy storages, said first busbar having a busbar section and multiple contact sections, each said multiple contact sections having a fastening region and a safety region, said fastening region being electrically conductively fastened on the terminal connection of respective ones of the energy storages to form an electrically conductive connection between the first busbar and the terminal connection, said safety region being encased by a surface layer and configured to interrupt the electrically conductive connection when a current flowing through the safety region exceeds a current threshold value; and
a second busbar arranged on the end side of the energy storages and electrically insulatingly arranged on the first busbar, said second busbar having multiple contact elements, with at least one of the contact elements being electrically conductively fastened to a respective one of the energy storages.

16. The energy storage arrangement of claim 15, wherein the energy storages are fastened on the fastening regions and/or on the contact elements by means of a welding connection.

17. The energy storage arrangement of claim 15, wherein the housing of each of the energy storages is configured cup-shaped and has a cylindrical outer shape.

18. A motor vehicle, comprising:
at least one energy storage arrangement, said at least one energy storage arrangement comprising
multiple energy storages, each having a terminal connection and a housing, said terminal connection being arranged at a respective end side of the energy storages and lying on an electrostatic potential of a first terminal, said housing lying on an electrostatic potential of a second terminal;
a first busbar arranged at the end side of the energy storages, said first busbar having a busbar section and multiple contact sections, each said multiple contact sections having a fastening region and a safety region, said fastening region being electrically conductively fastened on the terminal connection of respective ones of the energy storages to form an electrically conductive connection between the first busbar and the terminal connection, said safety region being encased by a surface layer and configured to interrupt the electrically conductive connection when a current flowing through the safety region exceeds a current threshold value; and
a second busbar arranged on the end side of the energy storages and electrically insulatingly arranged on the first busbar, said second busbar having multiple contact elements, with at least one of the contact elements being electrically conductively fastened to a respective one of the energy storages.
